(19) United States
(12) Patent Application Publication
(10) Pub. No.: US 2024/0128160 A1
(43) Pub. Date: Apr. 18, 2024

(54) SEMICONDCUTOR STRUCTURES AND METHODS OF SEMICONDUCTOR STRUCTURE

(71) Applicant: Semiconductor Manufacturing International (Shanghai) Corporation, Shanghai (CN)

(72) Inventors: Zhaoxu SHEN, Shanghai (CN); Yang LI, Shanghai (CN); Junwei GUO, Shanghai (CN); Yue YIN, Shanghai (CN)

(21) Appl. No.: 18/378,060

(22) Filed: Oct. 9, 2023

(30) Foreign Application Priority Data
Oct. 13, 2022 (CN) 202211258163.0

(51) Int. Cl. H01L 23/48; H01L 21/02; H01L 21/28; H01L 21/768

(52) U.S. Cl. CPC H01L 23/481; H01L 21/02592; H01L 21/28088; H01L 21/76802

(57) ABSTRACT

A semiconductor structure includes a substrate; a first electrode layer over the substrate; a dielectric layer on a sidewall surface of the first electrode layer; and a second electrode layer over the substrate. The first electrode layer, the dielectric layer, and the second electrode layer are arranged in a direction parallel to a surface of the substrate.

### CROSS-REFERENCES TO RELATED APPLICATION

This application claims the priority of Chinese Patent Application No. 202211258163.0, filed on Oct. 13, 2022, the content of which is incorporated by reference in its entirety.

### TECHNICAL FIELD

The present disclosure generally relates to the field of semiconductor manufacturing technologies and, more particularly, relates to semiconductor structures and methods for forming the semiconductor structures.

### BACKGROUND

In semiconductor industry, dimensions of components within integrated circuits (ICs) have been continually reduced to minimize the volume of packaged structures. This requires dimension reduction for all components within the integrated circuits.

It poses a significant challenge for capacitors to decrease the occupied area, while maintaining the same or higher capacitance.

### SUMMARY

One embodiment of the present disclosure provides a semiconductor structure. The semiconductor structure includes a substrate; a first electrode layer over the substrate; a dielectric layer on a sidewall surface of the first electrode layer; and a second electrode layer over the substrate. The first electrode layer, the dielectric layer, and the second electrode layer are arranged in a direction parallel to a surface of the substrate.

Another embodiment of the present disclosure provides a method for forming a semiconductor structure. The method includes providing a substrate; forming a first dielectric layer over the substrate; forming a first opening through the first dielectric layer; forming a first electrode layer in the first opening; forming a dielectric layer on a sidewall surface of the first electrode layer; removing the first dielectric layer and forming a second electrode layer over the substrate, wherein the second electrode layer is electrically isolated from the first electrode layer by the dielectric layer, and the first electrode layer, the dielectric layer, and the second electrode layer are arranged in a direction parallel to a surface of the substrate.

### BRIEF DESCRIPTION OF THE DRAWINGS

FIGS. 1 to 6A illustrate schematic diagrams of semiconductor structure at various stages during a formation process according to some embodiments of the present disclosure.

FIG. 6B illustrates an exemplary semiconductor structure according to some embodiments of the present disclosure.

FIGS. 7 to 9 illustrate schematic diagrams of semiconductor structure at various stages during a formation process according to some embodiments of the present disclosure.

FIGS. 10 to 13 illustrate schematic diagrams of semiconductor structure at various stages during a formation process according to some embodiments of the present disclosure.

FIGS. 14 to 16 illustrate schematic diagrams of semiconductor structure at various stages during a formation process according to some embodiments of the present disclosure.

### DETAILED DESCRIPTION

In order to make the above-mentioned objectives, features, and advantageous effects of the present invention more comprehensible, the following detailed description of embodiments of the present disclosure is provided in conjunction with the accompanying drawings.

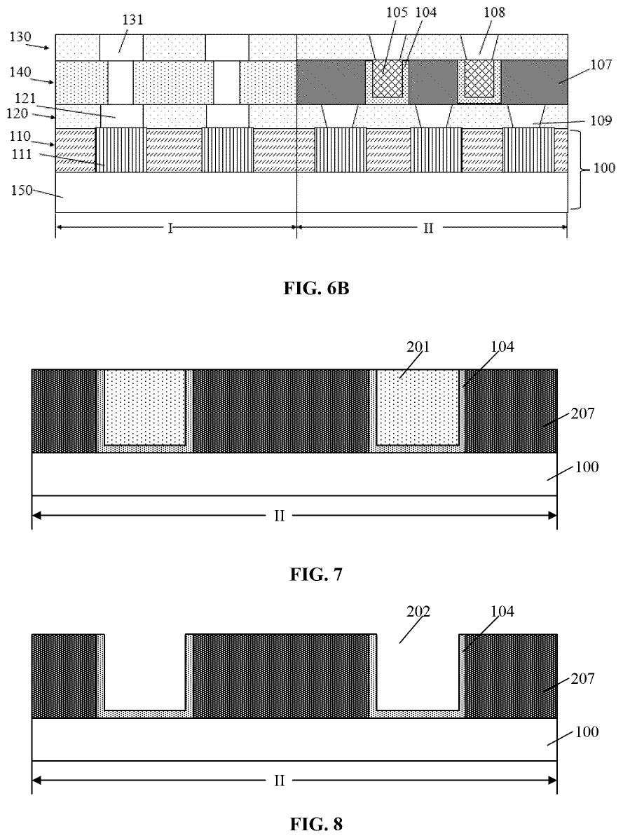

FIGS. 1 to 6A illustrate schematic diagrams of semiconductor structure at various stages during a formation process according to some embodiments of the present disclosure. FIG. 6B illustrates an exemplary semiconductor structure according to some embodiments of the present disclosure.

Referring to FIG. 1, a substrate 100 is provided.

The substrate 100 includes a first region I and a second region II, referring to FIG. 6B. The substrate 100 may include: a base 150 and a device layer 110 over the base 150. The device layer 110 may include device structures 111. The device structures 111 may include, for example, transistors, diodes, triodes, capacitors, inductors, and/or conductive structures.

Optionally, a first interconnection layer 120 may be formed over the device layer 110. For example, the first interconnection layer 120 over the first region I may include a first electrical connection structure 121, and the first electrical connection structure 121 is electrically connected to the device structures 111, as shown in FIG. 6B.

In one embodiment, the material of the substrate 100 includes silicon.

In other embodiments, the material of the substrate 100 includes, for example, silicon carbide, silicon germanium, multi-element semiconductor materials including Group III-V elements, silicon-on-insulator (SOI), and/or germanium-on-insulator (GOI). For example, the Group III-V elements may form multi-element semiconductor materials including InP, GaAs, Opening, InAs, InSb, InGaAs, and/or InGaAsP.

FIGS. 1-5 and 6A illustrate exemplary structures at various stages during a formation process over region II of the substrate 100.

For example, referring to FIG. 1, a first dielectric layer 101 is formed over the second region II of the substrate 100. A first opening 102 is formed through the first dielectric layer 101 and over the substrate 100.

The material of the first dielectric layer 101 includes dielectric material. Examples of the dielectric material may include silicon oxide, silicon nitride, silicon carbide, silicon oxycarbide, silicon oxynitride, aluminum oxide, aluminum nitride, silicon carbonitride, silicon carbon oxynitride, or a combination thereof.

In one embodiment, the material of the first dielectric layer 101 includes silicon oxide.

Subsequently, a first electrode layer and a dielectric layer may be formed in the first opening 102. For example, the dielectric layer may be formed on the sidewall surface and the bottom surface of the first opening. The first electrode layer may be located on the dielectric layer.

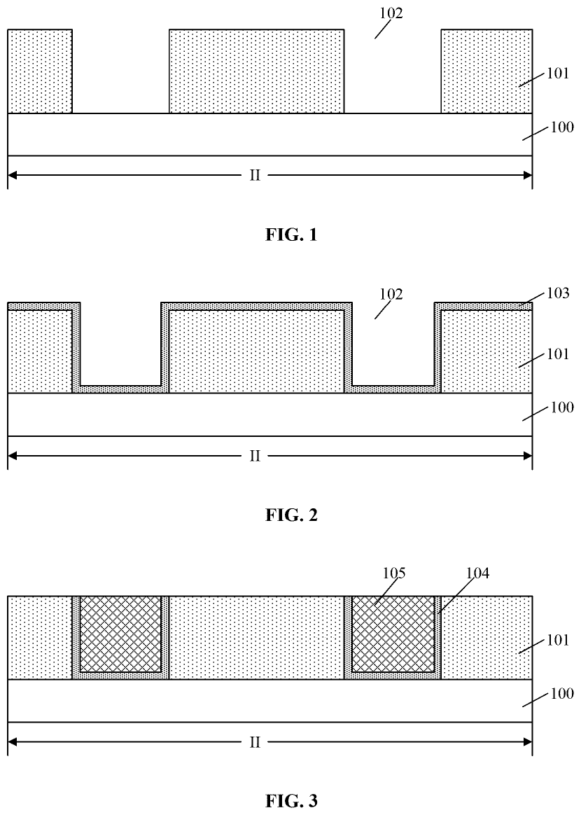

As shown in FIG. 2, a dielectric material layer 103 is formed on the sidewall surface and the bottom surface of the first opening 102, as well as on the top surface of the first dielectric layer 101.

The material of the dielectric material layer 103 includes dielectric material. Examples of the dielectric material may include silicon dioxide, silicon nitride, silicon carbide, silicon oxycarbide, silicon oxynitride, aluminum oxide, aluminum nitride, silicon carbonitride, silicon oxycarbonitride, or a combination thereof.

In one embodiment, the material of the dielectric material layer 103 differs from that of the first dielectric layer 101.

In one embodiment, the material of the dielectric material layer 103 includes silicon nitride.

Referring to FIG. 3, a dielectric layer 104 is formed in the first opening 102 and a first electrode layer 105 is formed on the dielectric layer 104. In one embodiment, a first electrode material layer may be formed on the dielectric material layer 103 of FIG. 2. The first electrode material layer and the dielectric material layer 103 may be planarized until the surface of the first dielectric layer 101 is exposed, thereby forming the structure shown in FIG. 3.

The material of the first electrode layer 105 includes metal or metal nitride. Examples of the metal may include copper, aluminum, tungsten, cobalt, nickel, tantalum, or a combination thereof. Examples of the metal nitride may include tantalum nitride, titanium nitride, or a combination thereof.

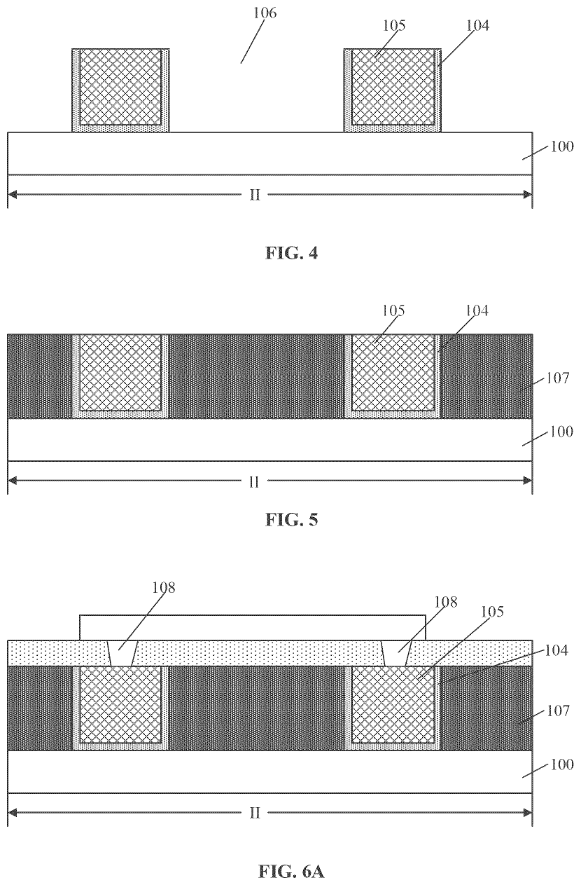

Subsequently, the first dielectric layer 101 is removed, and a second electrode layer may be formed over the second region II of the substrate. The second electrode layer is electrically isolated from the first electrode layer 105 by the dielectric layer 104. The first electrode layer 105, the dielectric layer 104, and the second electrode layer are arranged parallel to the surface of the substrate 100, as illustrated in FIGS. 4-5.

As shown in FIG. 4, the first dielectric layer 101 is removed from the semiconductor structure shown in FIG. 3, and a second opening 106 is formed over the second region II of the substrate.

Referring to FIG. 5, a second electrode layer 107 is formed, e.g., by forming a second electrode material layer in the second opening 106 and on the first electrode layer 105. The second electrode material layer may be planarized until the surface of the first electrode layer 105 is exposed, thereby forming the structure shown in FIG. 5.

The material of the second electrode layer 107 includes metal or metal nitride. Examples of the metal may include copper, aluminum, tungsten, cobalt, nickel, tantalum, or a combination thereof. Examples of the metal nitride may include tantalum nitride, titanium nitride, or a combination thereof.

As such, the first electrode layer 105, the dielectric layer 104, and the second electrode layer 107 are formed over the substrate 100. The first electrode layer 105, the dielectric layer 104, and the second electrode layer 107 are arranged in a direction parallel to the surface of the substrate 100. In this manner, the area occupied by the capacitor structure, formed by the first electrode layer 105, the dielectric layer 104, and the second electrode layer 107, along the direction parallel to the substrate surface may be reduced. This may allow the formation of more capacitors within a fixed area, thereby increasing the density of the capacitor structures and enhancing the energy storage capability of the capacitor structures.

In one embodiment, during formation process, referring to FIG. 6B, a second interconnection layer 130 is formed over the first region I, as well as the first dielectric layer 101 of FIG. 3 in the second region II. A second electrical connection structure 131 is formed in a second interconnection layer 130 over the first region I of the substrate 100. For example, the second electrical connection structure 131 is electrically connected to the first electrical connection structure 121 of the first interconnection layer 120 over the first region I of the substrate 100.

In one embodiment, a first connection layer 109 is formed in the first interconnection layer 120 (e.g., that is formed over the device layer 110), in the second region II, and a second connection layer 108 is formed in the second interconnection layer 130 in the second region II, as shown in FIG. 6B. The first connection layer 109 of the first interconnection layer 120 in the second region II is electrically connected to the second electrode layer 107. The second connection layer 108 of the second interconnection layer 130 in the second region II is electrically connected to the first electrode layer 105.

In other embodiments (although not shown), the first connection layer (e.g., the first connection layer 109) of the first interconnection layer (e.g., the first interconnection layer 120) in the second region II may be electrically connected to the first electrode layer (e.g., the first electrode layer 105), and the second connection layer (e.g., the second connection layer 108) may be electrically connected to the second electrode layer (e.g., the second electrode layer 107).

In various embodiments, the first electrode layer 105 is connected to an external power source through the first connection layer 109 in the first interconnection layer 120, and the second electrode layer 107 are connected to an external power source through the second connection layer 108 in the second interconnection layer 130. The formation process of the capacitor structure can be integrated with the subsequent metal process of the semiconductor structure, which simplifies the overall process flow.

As shown in FIG. 6A, the semiconductor structure includes a substrate 100; a first electrode layer 105 over the substrate 100; a dielectric layer 104 over the sidewall surface of the first electrode layer 105; and a second electrode layer 107 over the substrate 100. For example, the first electrode layer 105, the dielectric layer 104, and the second electrode layer 107 are arranged in a direction parallel to the surface of the substrate 100.

In one embodiment, the dielectric layer 104 is located on the sidewall surface and the bottom surface of the first electrode layer 105.

In one embodiment, as shown in FIG. 6B, the substrate 100 includes a first region I and a second region II. The substrate 100 may include: a base 150; a device layer 110 over the base 150. The device layer 110 may include device structures 111. A first interconnection layer 120 may be located over the device layer 110 of the first region I and the second region II. For example, the first interconnection layer 120 in the first region I may include a first electrical connection structure 121, and the first electrical connection structure 121 is electrically connected to the device structures 111. The first electrode layer 105 and the second electrode layer 107 are located in the second region II. In one embodiment, the first electrode layer 105 and the second electrode layer 107 are located only in the second region II.

In one embodiment, a first dielectric layer 140 is over the first region I of the substrate 100. A second interconnection layer 130 is over the first dielectric layer. For example, the second interconnection layer 130 in the first region I includes a second electrical connection structure 131, and the second electrical connection structure 131 is electrically connected to the first electrical connection structure 121 under the second interconnection layer 130, as shown in FIG. 6B.

In one embodiment, a first connection layer 109 is located in the first interconnection layer 120 in the second region II. A second connection layer 108 is located in the second interconnection layer 130 in the second region II. For example, the first connection layer 109 is electrically connected to the second electrode layer 107, and the second connection layer 108 is electrically connected to the first electrode layer 105, as shown in FIG. 6B. Or the first connection layer may be electrically connected to the first electrode layer, and the second connection layer may be electrically connected to the second electrode layer.

In one embodiment, the material of the first electrode layer 105 includes metal or metal nitride. The material of the second electrode layer 107 includes metal or metal nitride. The metal may include titanium, cobalt, copper, aluminum, or a combination thereof. The metal nitride may include titanium nitride, tantalum nitride, or a combination thereof.

In one embodiment, the material of the dielectric layer 104 includes dielectric material, for example, having a dielectric constant greater than 3.9. The dielectric material may include aluminum oxide, hafnium oxide, or a combination thereof.

In one embodiment, the material of the first dielectric layer 140 includes dielectric material, for example, having a dielectric constant less than 3.9. The dielectric material may include silicon oxide, silicon nitride, silicon carbide, or a combination thereof.

FIGS. 7 to 9 illustrate another exemplary semiconductor structure at various stages during a formation process according to some embodiments of the present disclosure.

In one embodiment, the structure illustrated in FIG. 7 may be formed based on the exemplary structure illustrated in FIG. 2, where a dielectric material layer 103 is formed on the sidewall surface and the bottom surface of the first opening 102, as well as on the top surface of the first dielectric layer 101.

A sacrificial layer 201 is then formed in the first opening 102, a second electrode layer 207 is formed over the substrate 100, as shown in FIG. 7.

For example, the sacrificial layer 201 may be formed by forming a sacrificial material layer (not illustrated) on the dielectric material layer 103 of FIG. 2, followed by a planarization process on the sacrificial material layer and the dielectric material layer 103 until the surface of the first dielectric layer 101 is exposed, resulting in a dielectric layer 104 formed in the first opening 102 and the sacrificial layer 201 formed on the dielectric layer 104.

After the formation of the sacrificial layer 201, the first dielectric layer 101 is removed, and a second opening is formed over the substrate 100 exposing the sidewall surface of the dielectric layer 104. A second electrode material layer may be formed in the second opening and on the sacrificial layer 201. The second electrode material layer is planarized until the surface of the sacrificial layer 201 is exposed, thereby forming a second electrode layer 207, as shown in FIG. 7.

In one embodiment, the material of the sacrificial layer 201 includes amorphous carbon.

As shown in FIG. 8, the sacrificial layer 201 is removed, and a third opening 202 is formed in the dielectric layer 104.

The process for removing the sacrificial layer 201 may include wet etching or reactive ion etching. The etching solution in the wet etching process may include a weak alkaline solution. For example, the weak alkaline solution may include ammonia water.

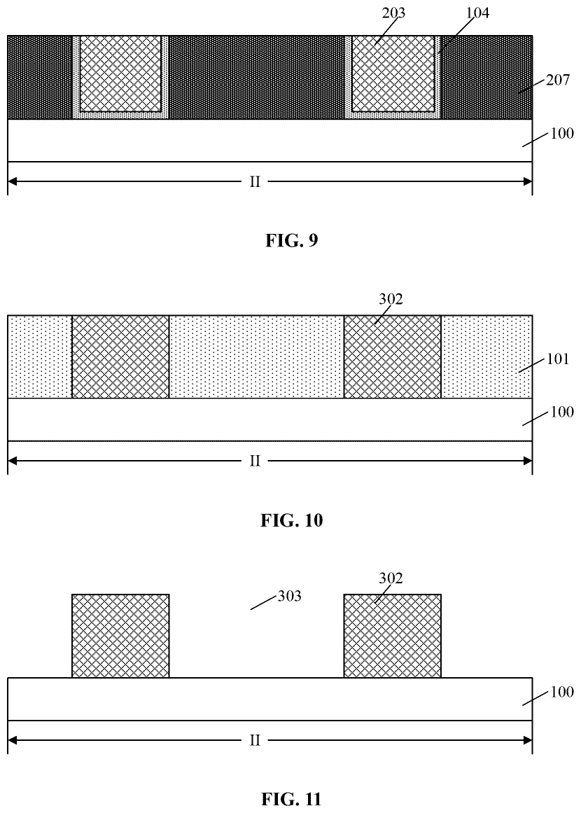

Referring to FIG. 9, a first electrode layer 203 is formed in the third opening 202, e.g., by forming a first electrode material layer in the third opening 202 and on the second electrode layer 207 and planarizing the first electrode material layer until the surface of the second electrode layer 207 is exposed.

The semiconductor structure shown in FIG. 9 may be included in the structure shown in FIG. 6B, similar as the structure shown in FIG. 5 being included in the structure shown in FIG. 6B. Corresponding structures and methods are not repeated herein.

FIGS. 10 to 13 illustrate another exemplary schematic semiconductor structure at various stages during a formation process according to some embodiments of the present disclosure.

The structure illustrated in FIG. 10 may be formed based on the exemplary structure illustrated in FIG. 1. As shown in FIG. 10, a first electrode layer 302 is formed in the first opening 102 of the structure in FIG. 10, by forming a first electrode material layer in the first opening 102 and planarizing the first electrode material layer until the surface of the first dielectric layer 101 is exposed.

Referring to FIG. 11, after the formation of the first electrode layer 302, the first dielectric layer 101 is removed, and a second opening 303 is formed over the substrate 100. The second opening 303 exposes the sidewall surface of the first electrode layer 302.

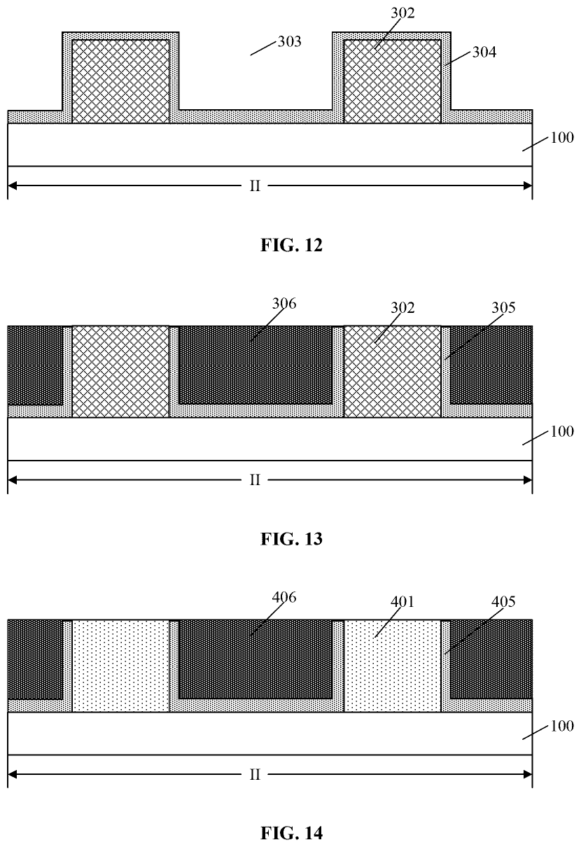

Referring to FIG. 12, a dielectric material layer 304 is formed on the sidewall surface and the top surface of the first electrode layer 302, as well as on the bottom surface of the second opening 303.

Referring to FIG. 13, a second electrode layer 306 and a dielectric layer 305 are formed. For example, a second electrode material layer may be formed on the dielectric material layer 304. The second electrode material layer and the dielectric material layer 304 are planarized until the surface of the first electrode layer 302 is exposed, thereby forming the second electrode layer 306 and the dielectric layer 305. The dielectric layer 305 is located on the sidewall surface of the first electrode layer 302 and over the substrate 100, as shown in FIG. 13.

The semiconductor structure shown in FIG. 13 may be included in the structure shown in FIG. 6B, similar as the structure shown in FIG. 6A being included in the structure shown in FIG. 6B. Corresponding structures and methods are not repeated herein. The semiconductor structure described in FIG. 13 differs from the semiconductor structure in FIG. 6A in that the dielectric layer 305 is further formed between the substrate 100 and a bottom surface of the second electrode layer 306.

FIGS. 14-16 illustrates another exemplary semiconductor structure at various stages during a formation process according to some embodiments of the present disclosure.

The structure illustrated in FIG. 14 may be formed based on the exemplary structure illustrated in FIG. 1.

As shown in FIG. 14, a second electrode layer 406 and a dielectric layer 405 are formed, e.g., by forming a sacrificial material layer in the first opening 102 and planarizing the sacrificial material layer the surface of the first dielectric layer 101 is exposed, thereby forming a sacrificial layer 401 in the first opening 102. After the formation of the sacrificial layer 401, the first dielectric layer 101 is removed, and a second opening is formed over the substrate 100 to expose the sidewall surface of the sacrificial layer 401. A dielectric material layer may be formed on the sidewall surface and the top surface of the sacrificial layer 401, as well as the bottom surface of the second opening. A second electrode material layer may be formed on the dielectric material layer. The second electrode material layer and the dielectric material layer may be planarized until the surface of the sacrificial layer 401 is exposed, thereby forming the second electrode layer 406 and the dielectric layer 405 as shown in FIG. 14.

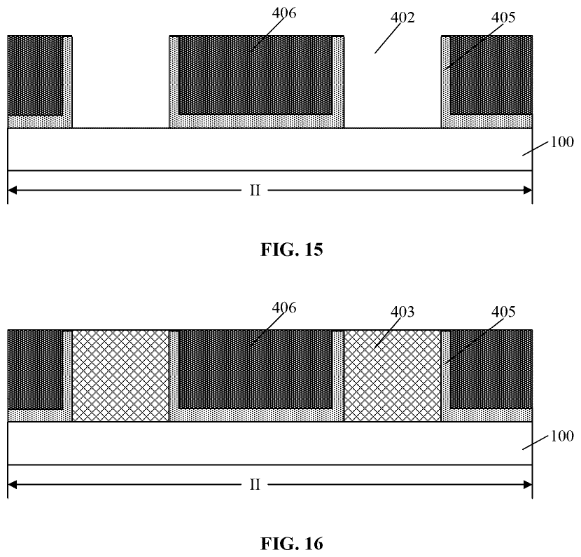

Referring to FIG. 15, the sacrificial layer 401 is removed, and a third opening 402 is formed through the dielectric layer 405.

Referring to FIG. 16, a first electrode layer 403 is formed, e.g., by forming a first electrode material layer in the third opening 402 and on the second electrode layer 406. The first electrode material layer may be planarized until the surface of the second electrode layer 406 is exposed, thereby forming the first electrode layer 403.

The semiconductor structure shown in FIG. 16 may be included in the structure shown in FIG. 6B, similar as the structure shown in FIG. 13 being included in the structure shown in FIG. 6B. Corresponding structures and methods are not repeated herein.

Compared to existing technology, the technical solutions of the present disclosure provide following advantageous effects.

The technical solution of the present disclosure involves forming a first electrode layer, a dielectric layer, and a second electrode layer over a substrate. The first electrode layer, the dielectric layer, and the second electrode layer may be arranged in a direction parallel to a surface of the substrate. As such, the area occupied by the capacitor structure formed by the first electrode layer, the dielectric layer, and the second electrode layer along the direction parallel to the substrate surface may be reduced. This reduction in occupied area may allow for the formation of a greater number of capacitors within the fixed area, thereby increasing the density of the capacitor structures and enhancing the energy storage capability of the capacitor structures.

Furthermore, the disclosed semiconductor structure includes: a first connection layer in a first interconnection layer in the second region, a second connection layer in a second interconnection layer in the second region. For example, the first connection layer is electrically connected to the second electrode layer, and the second connection layer is electrically connected to the first electrode layer, or the first connection layer may be electrically connected to the first electrode layer, and the second connection layer may be electrically connected to the second electrode layer. The first electrode layer and the second electrode layer may be connected to an external power source through the first connection layer in the first interconnection layer and the second connection layer in the second interconnection layer, respectively. The formation process of the capacitor structure can be integrated with the back-end metal process of the semiconductor structure, simplifying the overall process flow.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A semiconductor structure, comprising:
a substrate;
a first electrode layer over the substrate;
a dielectric layer on a sidewall surface of the first electrode layer; and
a second electrode layer over the substrate, wherein the first electrode layer, the dielectric layer, and the second electrode layer are arranged in a direction parallel to a surface of the substrate.

2. The semiconductor structure according to claim 1, wherein the dielectric layer is further formed between a bottom surface of the first electrode layer and the substrate.

3. The semiconductor structure according to claim 1, wherein the dielectric layer on the sidewall surface of the first electrode layer is above the surface of the substrate.

4. The semiconductor structure according to claim 1, wherein the substrate comprises a first region and a second region, and the substrate further comprises: a base and a device layer over the base, wherein the device layer includes a device structure; and a first interconnection layer is formed over the device layer, wherein the first interconnection layer over the first region of the substrate includes a first electrical connection structure, the first electrical connection structure is electrically connected to the device structure, and the first electrode layer and the second electrode layer are in the second region.

5. The semiconductor structure according to claim 4, further comprising:
a first dielectric layer over the first region of the substrate; and
a second interconnection layer over the first dielectric layer, wherein the second interconnection layer over the first region includes a second electrical connection structure, and the second electrical connection structure is electrically connected to the first electrical connection structure.

6. The semiconductor structure according to claim 5, further comprising:
a first connection layer formed in the first interconnection layer over the second region of the substrate; and
a second connection layer formed in the second interconnection layer over the second region, wherein:
the first connection layer is electrically connected to the second electrode layer, and the second connection layer is electrically connected to the first electrode layer, or
the first connection layer is electrically connected to the first electrode layer, and the second connecting layer is electrically connected to the second electrode layer.

7. The semiconductor structure according to claim 1, wherein each of the first electrode layer and the second electrode layer is made of a material comprising metal or metal nitride, the metal comprises titanium, cobalt, copper, aluminum, or a combination thereof, and the metal nitride comprises titanium nitride, tantalum nitride, or a combination thereof.

8. The semiconductor structure according to claim 1, wherein the dielectric layer comprises a dielectric material having a dielectric constant greater than 3.9, and the dielectric material comprises aluminum oxide, hafnium oxide, or a combination thereof.

9. The semiconductor structure according to claim 5, wherein the first dielectric layer comprises a dielectric material having a dielectric constant less than 3.9, and the dielectric material comprises silicon oxide, silicon nitride, or silicon oxycarbide, or a combination thereof.

10. A method for forming a semiconductor structure, comprising:
providing a substrate;
forming a first dielectric layer over the substrate;
forming a first opening through the first dielectric layer;
forming a first electrode layer in the first opening;
forming a dielectric layer on a sidewall surface of the first electrode layer;
removing the first dielectric layer and forming a second electrode layer over the substrate, wherein the second electrode layer is electrically isolated from the first electrode layer by the dielectric layer, and the first electrode layer, the dielectric layer, and the second electrode layer are arranged in a direction parallel to a surface of the substrate.

11. The method for forming the semiconductor structure according to claim 10, wherein the dielectric layer is further formed between a bottom surface of the first electrode layer and the substrate.

12. The method for forming the semiconductor structure according to claim 11, wherein the second electrode layer is formed after the first electrode layer is formed, and the first electrode layer and the dielectric layer are formed by performing:
forming a dielectric material layer on a sidewall surface and a bottom surface of the first opening, as well as on a top surface of the first dielectric layer;
forming a first electrode material layer on the dielectric material layer;
planarizing the first electrode material layer and the dielectric material layer until the top surface of the first dielectric layer is exposed, thereby forming a dielectric layer in the first opening and the first electrode layer on the dielectric layer;
forming a second opening over the substrate;
forming a second electrode material layer in the second opening and on the first electrode layer; and
planarizing the second electrode material layer until the surface of the first electrode layer is exposed, thereby forming a second electrode layer.

13. The method for forming the semiconductor structure according to claim 11, wherein the first electrode layer is formed after the second electrode layer is formed, and the first electrode layer, the dielectric layer, and the second electrode layer are formed by performing:
forming a dielectric material layer on a sidewall surface and a bottom surface of the first opening, as well as on a top surface of the first dielectric layer;
forming a sacrificial material layer on the dielectric material layer;
planarizing the sacrificial material layer and the dielectric material layer until the top surface of the first dielectric layer is exposed, thereby forming a dielectric layer in the first opening and a sacrificial layer on the dielectric layer;
forming a second opening over the substrate by removing the first dielectric layer after forming the sacrificial layer, the second opening exposing a sidewall surface of the dielectric layer;
forming a second electrode material layer in the second opening and on the sacrificial layer;
planarizing the second electrode material layer until a surface of sacrificial layer is exposed, thereby forming the second electrode layer;
forming a third opening through the dielectric layer by removing the sacrificial layer;
forming a first electrode material layer in the third opening and on the second electrode layer;
planarizing the first electrode material layer until a surface of the second electrode layer is exposed, thereby forming the first electrode layer.

14. The method for forming the semiconductor structure according to claim 10, wherein the dielectric layer on the sidewall surface of the first electrode layer is formed further above the substrate.

15. The method for forming the semiconductor structure according to claim 14, wherein the second electrode layer is formed after the first electrode layer is formed, and the first electrode layer, the dielectric layer, and the second electrode layer are formed by performing:
forming a first electrode material layer in the first opening;
planarizing the first electrode material layer until a surface of the first dielectric layer is exposed, thereby forming the first electrode layer in the first opening;
forming a second opening over the substrate by removing the first dielectric layer after forming the first electrode layer, the second opening exposing the sidewall surface of the first electrode layer;
forming a dielectric material layer on a sidewall surface and a top surface of the first electrode layer, as well as on a bottom surface of the second opening;
forming a second electrode material layer on the dielectric material layer; and
planarizing the second electrode material layer and the dielectric material layer until a surface of the first electrode layer is exposed, thereby forming the second electrode layer and the dielectric layer.

16. The method for forming the semiconductor structure according to claim 14, wherein the first electrode layer is formed after the second electrode layer is formed, and the first electrode layer, the dielectric layer, and the second electrode layer are formed by performing:
forming a sacrificial material layer in the first opening;
planarizing the sacrificial material layer until a surface of the first dielectric layer is exposed, thereby forming a sacrificial layer in the first opening;
forming a second opening over the substrate by removing the first dielectric layer after forming the sacrificial layer, the second opening exposing a sidewall surface of the sacrificial layer;
forming a dielectric material layer on the sidewall surface and a top surface of the sacrificial layer, as well as a bottom surface of the second opening;
forming a second electrode material layer on the dielectric material layer;
planarizing the second electrode material layer and the dielectric material layer until a surface of the sacrificial layer is exposed, thereby forming the second electrode layer and the dielectric layer;
forming a third opening through the dielectric layer by removing the sacrificial layer;
forming a first electrode material layer in the third opening and on the second electrode layer; and
planarizing the first electrode material layer until a surface of the second electrode layer is exposed, thereby forming the first electrode layer.

17. The method for forming the semiconductor structure according to claim 10, wherein the substrate comprises a first region and a second region, and the substrate further comprises: a base and a device layer over the base, wherein the device layer includes a device structure; and
a first interconnection layer is formed over the device layer, wherein the first interconnection layer over the first region of the substrate includes a first electrical connection structure, the first electrical connection structure is electrically connected to the device structure, and the first electrode layer and the second electrode layer are in the second region.

18. The method for forming the semiconductor structure according to claim 17, further comprising:
forming a second interconnection layer on the first dielectric layer; and
forming a second electrical connection structure in the second interconnection layer in the first region, wherein the second electrical connection structure is electrically connected to the first electrical connection structure in the first interconnection layer.

19. The method for forming the semiconductor structure according to claim 18, comprising:
forming a first connection layer in the first interconnection layer in the second region; and
forming a second connection layer in the second interconnection layer in the second region, wherein:
the first connection layer is electrically connected to the second electrode layer, and the second connection layer is electrically connected to the first electrode layer, or
the first connection layer is electrically connected to the first electrode layer, and the second connection layer is electrically connected to the second electrode layer.

20. The method for forming the semiconductor structure according to claim 13, wherein the sacrificial layer is made of a material comprising amorphous carbon.
